(19) United States
(12) Patent Application Publication
(10) Pub. No.: US 2010/0026353 A1
(43) Pub. Date: Feb. 4, 2010

(54) Semiconductor device for constantly maintaining data access time

(75) Inventors: Yong-gwon Jeong, Uiwang-si (KR); Kwang-il Park, Yongin-si (KR); Min-su Ahn, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/453,137

(22) Filed: Apr. 30, 2009

(30) Foreign Application Priority Data
Jul. 30, 2008 (KR) 10-2008-0074715

(51) Int. Cl. H03L 7/00

(52) U.S. Cl. 327/161

(57) ABSTRACT

The semiconductor device may include a calibration circuit, a control unit, and a delay unit. The calibration circuit may be configured to output an output signal. The control unit may be configured to generate and output the control signal in response to the output signal of the calibration circuit. The control unit may generate the control signal by using a correlation between a signal transmission speed of the semiconductor device and the output signal of the calibration circuit. The delay unit may be configured to delay a clock signal in response to the control signal and output the delayed clock signal to the output driver.

### PRIORITY STATEMENT

This application claims the benefit of Korean Patent Application No. 10-2008-0074715, filed on Jul. 30, 2008, in the Korean Intellectual Property Office, the disclosure of which is incorporated herein in its entirety by reference.

### BACKGROUND

1. Field

Example embodiments relate to a semiconductor device, for example, to a semiconductor device for constantly maintaining data access time.

2. Description of the Related Art

In general, signal transmission speed of a semiconductor device is sensitive to process, voltage, and temperature (PVT) variations.

Adding a voltage source can mitigate the voltage variations. However, the process variations and the temperature variations are still problematic. Also, the process variations generally have a greater affect than the temperature variations on the operation of the semiconductor device.

For example, when dynamic random access memory (DRAM) outputs data in synchronization with a clock signal, a time difference exists between the clock signal and the data output from the DRAM in supposed synchronization with the clock signal, and such a time difference is referred to as data access time. The data access time occurs according to the PVT variations and may present relatively serious timing issues as a device operates at higher speeds.

### SUMMARY

Example embodiments provide a semiconductor device for constantly maintaining data access time taken between a clock signal and data output from the semiconductor device in synchronization with the clock signal, by delaying the clock signal for a desired (or alternatively, predetermined) period of time.

According to an embodiment, there is provided a semiconductor device including a calibration circuit configured to output an output signal, a control unit configured to generate and output a control signal in response to the output signal of the calibration circuit, where the control unit generates the control signal by using a correlation between a signal transmission speed of the semiconductor device and the output signal of the calibration circuit, and a delay unit configured to delay a clock signal in response to the control signal and output the delayed clock signal to the output driver.

The calibration circuit may include a ZQ calibration circuit.

The delay unit may delay the clock signal in response to the control signal so that that a constant time period is maintained between the clock signal and data output from the semiconductor device in synchronization with the clock signal.

The delay unit may include a plurality of delays configured to delay the clock signal, and a switch unit configured to select and output one of the clock signal and an output signal of one of the plurality of delays, in response to the control signal.

The switch unit may include a plurality of switches, with the plurality of switches further including a reference switch configured to control a connection between input and output terminals of the delay unit, and a plurality of delay switches respectively configured to control a connection between output terminals of the corresponding plurality of delays and the output terminal of the delay unit.

Each of the plurality of delays may include an inverter chain having a plurality of inverters.

The plurality of switches of the switch unit may be fuses which are selectively one of cut and blown in response to the control signal.

The control unit may output the control signal that that turns on one of the plurality of switches of the switch unit and turns off a remaining of the plurality of switches of the switch unit.

The control unit may correlate the correlation between the signal transmission speed of the semiconductor device and the output signal of the calibration circuit if a source voltage of the semiconductor device is at a desired voltage level.

The control signal may include a plurality of bits.

The output driver may output data in synchronization with the delayed clock signal.

The output driver may include a switch configured to output the data in response to the delayed clock signal, a first inverter configured to receive and invert the data output from the switch, a second inverter configured to receive and invert an output of the first inverter, and a DQ pad configured to a receive an output of the second inverter.

The delay unit may output the delayed clock signal to the output driver through a plurality of lines and inverters.

The delay unit may output the delayed clock signal to the output driver through at least one of a plurality of n-type metal-oxide-semiconductors (NMOSs) and p-type metal-oxide-semiconductors (PMOSs), where the NMOSs and the PMOSs may transmit the delayed clock signal at different speeds according to a size of a turn-on current for each of the at least one of the plurality of the NMOSs and the PMOSs.

According to an embodiment, a semiconductor device may include a control unit configured to generate and output a control signal in response to an output signal of a calibration circuit, where the control unit generates the control signal by using a correlation between a signal transmission speed of the semiconductor device and the output signal of the calibration circuit, and a delay unit configured to delay a clock signal in response to the control signal and to output the delayed clock signal to the output driver, where the delay unit delays the clock signal in response to the control signal such that a constant time period is maintained between the clock signal and data output from the semiconductor device in synchronization with the clock signal.

According to an embodiment, a semiconductor device may include a calibration circuit configured to output an output signal based on adjusting an internal impedance in response to a voltage level, a control unit configured to generate and output a control signal in response to the output signal, where the control unit generates the control signal by using a correlation between a signal transmission speed of the semiconductor device and the output signal of the calibration circuit, a delay unit configured to delay a clock signal in response to the control signal and output the delayed clock signal to an output driver, and the output driver configured to output data in synchronization with the delayed clock signal.

### BRIEF DESCRIPTION OF THE DRAWINGS

Example embodiments of the invention will be more clearly understood from the following detailed description taken in conjunction with the accompanying drawings in which:

FIG. 1 is a schematic diagram of a semiconductor device according to an embodiment of the invention;

FIG. 2 is a circuit diagram of a delay unit illustrated in FIG. 1;

FIG. 3 is a schematic diagram of a ZQ calibration circuit as an example of a calibration circuit illustrated in FIG. 1;

FIG. 4 is a graph showing a correlation between a signal transmission speed of the semiconductor device illustrated in FIG. 1 and an output signal of the calibration circuit illustrated in FIG. 1; and

FIG. 5 is a graph showing variations in data access time according to an embodiment of the invention, and variations in data access time according to conventional art.

### DETAILED DESCRIPTION OF THE EMBODIMENTS

Example embodiments will now be described more fully with reference to the accompanying drawings. Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures. The figures are intended to depict example embodiments and should not be interpreted to limit the intended scope of the claims. The accompanying figures are not to be considered as drawn to scale unless explicitly noted.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof. In this specification, the term “and/or” picks out each individual item as well as all combinations of them.

Unless otherwise defined, all terms (including technical and scientific terms) used herein have the same meaning as commonly understood by one of ordinary skill in the art to which example embodiments belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

When it is determined that a detailed description related to a related known function or configuration may make the purpose of example embodiments unnecessarily ambiguous, the detailed description thereof will be omitted. Also, terms used herein are defined to appropriately describe the exemplary embodiments and thus may be changed depending on a user, the intent of an operator, or a custom. Accordingly, the terms must be defined based on the following overall description within this specification.

Now, in order to more specifically describe example embodiments, example embodiments will be described in detail with reference to the attached drawings. However, example embodiments are not limited to the embodiments described herein, but may be embodied in various forms.

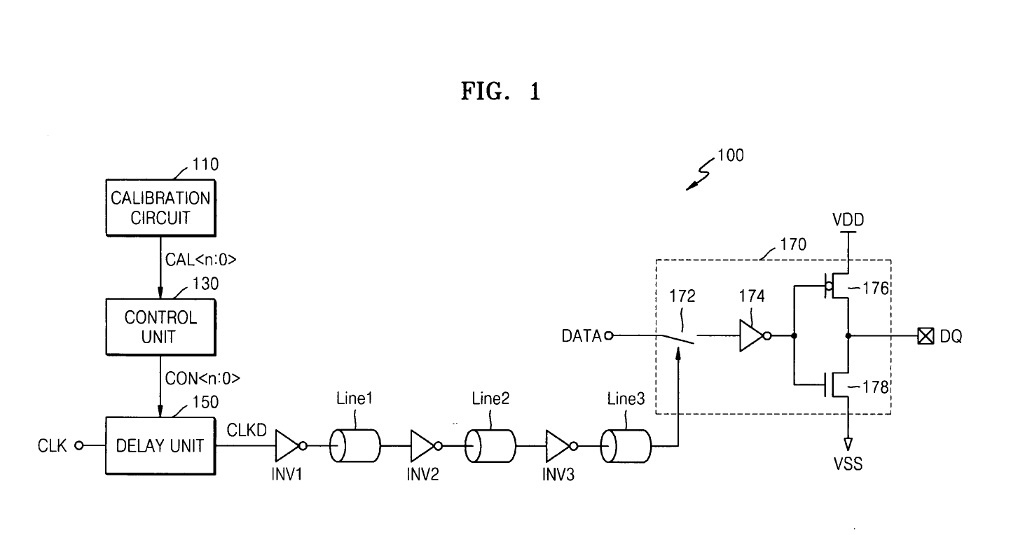

FIG. 1 is a schematic diagram of a semiconductor device 100 according to an embodiment of the invention.

Referring to FIG. 1, the semiconductor device 100 includes a calibration circuit 110, a control unit 130, a delay unit 150, and an output driver 170.

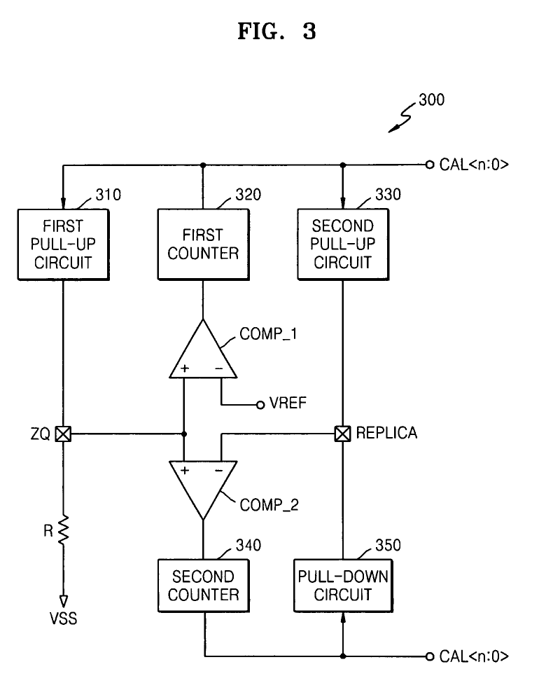

Although not shown in FIG. 1, the calibration circuit 110 may control the output driver 170. The semiconductor device 100 may match a line impedance to an output impedance by adjusting the output impedance. In general, the semiconductor device 100 adjusts the output impedance by using the calibration circuit 110. In more detail, an output signal CAL<n:0> of the calibration circuit 110 is output as a gate control signal for each of a plurality of transistors (not shown) of the output driver 170. According to an embodiment of the invention, a ZQ calibration circuit using a ZQ pin may be used as the calibration circuit 110. The ZQ calibration circuit will be described in more detail later with reference to FIG. 3. However, the calibration circuit 110 is not limited to the ZQ calibration circuit and another type of calibration circuit may be used as long as a desired (or alternatively, predetermined) correlation generally exists between a signal transmission speed of the semiconductor device 100 and the output signal CAL<n:0> of the calibration circuit 110, as will be described in detail later with reference to FIG. 4. Hereinafter, it may be assumed that the output signal CAL<n:0> of the calibration circuit 110 has n+1 bits (where n is a natural number).

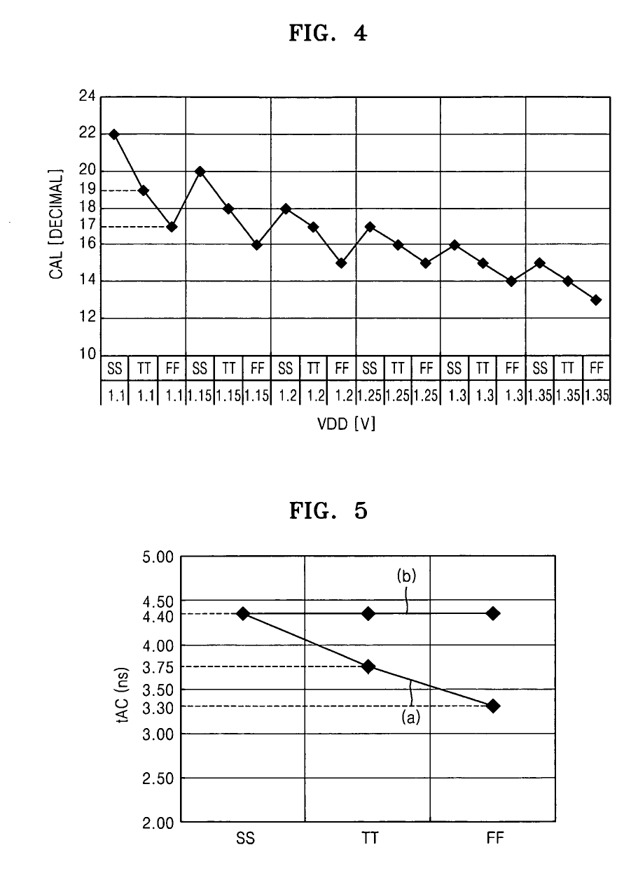

The control unit 130 outputs a control signal CON<n:0> to the delay unit 150 in response to the output signal CAL<n:0> of the calibration circuit 110. For example, the control signal 130 controls the delay unit 150 in response to the output signal CAL<n:0> of the calibration circuit 110. The control unit 130 generates the control signal CON<n:0> by using the correlation between the signal transmission speed of the semiconductor device 100 and the output signal CAL<n:0> of the calibration circuit 110. Hereinafter, it may be assumed that the control signal CON<n:0> has n+1 bits (where n is a natural number). The generating of the control signal CON<n:0> and the controlling of the delay unit 150, by using the correlation between the signal transmission speed of the semiconductor device 100 and the output signal CAL<n:0> of the calibration circuit 110, will be described in more detail later with reference to FIGS. 4 and 5.

The delay unit 150 delays a clock signal CLK in response to the control signal CON<n:0> and outputs a delayed clock signal CLKD to the output driver 170. The delay unit 150 delays the clock signal CLK in response to the control signal CON<n:0> so that a constant or unvarying time period is maintained between the clock signal CLK and data output from the semiconductor device 100 in synchronization with the delayed clock signal CLKD. Hereinafter, the time between the clock signal CLK and the data output from the semiconductor device 100 in synchronization with the delayed clock signal CLKD is referred to as data access time tAC. In general, the semiconductor device 100 may include a plurality of inverters INV1 through INV3 or a plurality of buffers (not shown) between lines Line1 through Line3. For example, if the inverters INV1 through INV3 are included between the lines Line1 through Line3, as illustrated in FIG. 1, the clock signal CLK may be applied to the output driver 170 through the lines Line1 through Line3, and the inverters INV1 through INV3. In this case, the clock signal CLK may pass through a plurality of n-type metal-oxide-semiconductors (NMOSs) or a plurality of p-type metal-oxide-semiconductors (PMOSs), and the NMOSs and the PMOSs may transmit the clock signal CLK at different speeds according to the sizes of their turn-on currents. Thus, the data access time tAC may vary such that the semiconductor device 100 may not operate normally. According to an embodiment of the invention, the delay unit 150 delays the clock signal CLK for a desired (or alternatively, predetermined) period of time and thus the data access time tAC may be constantly maintained regardless of the signal transmission speed of the semiconductor device 100.

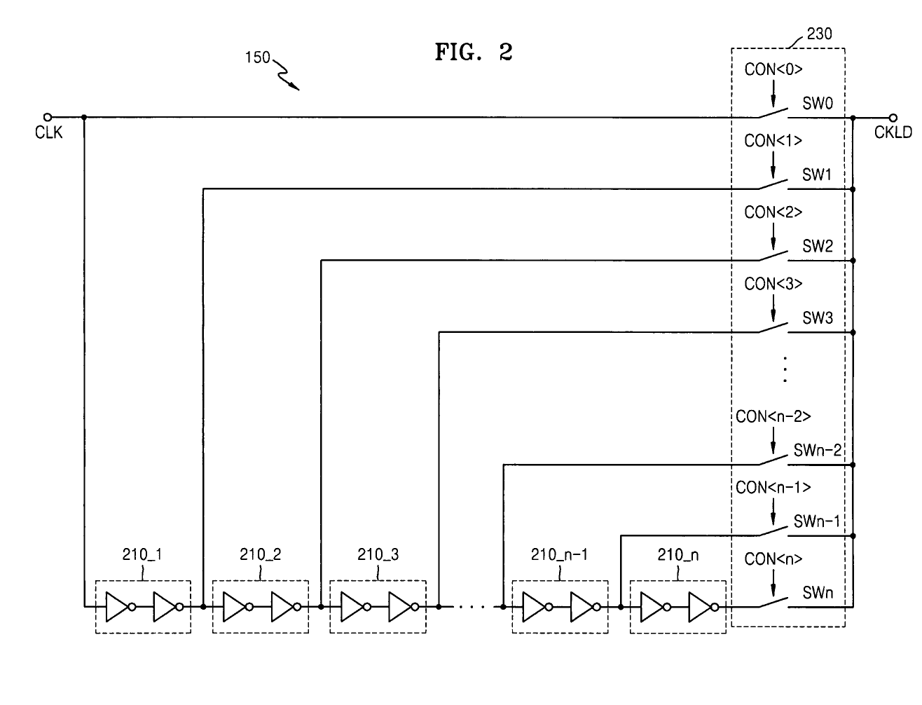

Although FIG. 1 shows that the delayed clock signal CLKD output from the delay unit 150 is applied to the output driver 170 through the lines Line1 through Line3 and the inverters INV1 through INV3, the example embodiments of the invention are not limited thereto. The same effect may also be achieved when the delayed clock signal CLKD, which is obtained by delaying the clock signal CLK transmitted through the lines Line1 through Line3 and the inverters INV1 through INV3, is applied to the output driver 170. The delay unit 150 will be described in more detail later with reference to FIG. 2.

The output driver 170 outputs data DATA in synchronization with the delayed clock signal CLKD. For example, the output driver 170 may include a switch 172, a first inverter 174, a second inverter, and a DQ pad DQ. The switch 172 may output the data DATA to the first inverter 174 in response to the delayed clock signal CLKD. The first inverter 174 may invert and output the data DATA to the second inverter. The second inverter may invert and output the output of the first inverter 174 to the DQ pad DQ. The second inverter may, for example, include an PMOS transistor 176 and an NMOS transistor 178 connected in series. A source of the PMOS transistor 176 may be connected to a source voltage VDD and a drain of the PMOS transistor 176 may be connected to a drain of the NMOS transistor 178. The drains of the PMOS and NMOS transistors 176 and 178 may also be connected to the DQ pad DQ. A source of the NMOS transistor 178 may be connected to a ground voltage VSS. Gates of the of the PMOS and NMOS transistors 176 and 178 may be connected to the output of the first inverter 174.

FIG. 2 is a circuit diagram of the delay unit 150 illustrated in FIG. 1.

Referring to FIGS. 1 and 2, the delay unit 150 may include first through nth delayers 210_1 through 210_{—}n, and a switch unit 230.

The first delayer 210_1 delays the clock signal CLK for a first period of time so as to output a first output signal. Although FIG. 2 shows that each of the first through nth delayers 210_1 through 210_{—}n is an inverter chain in which each inverter chain includes two inverters, example embodiments of the invention are not limited thereto. For example, each inverter chain may include more or less inverters. The first through nth delayers 210_1 through 210_{—}n may have another configuration as long as an input signal may be delayed for a desired (or alternatively, predetermined) period of time. The second delayer 210_2 delays the first output signal of the first delayer 210_1 for a second period of time so as to output a second output signal. Thus, a kth delayer (where k is a natural number, 2≦k≦n) may delay a k−1th output signal of a k−1th delayer for a kth period of time so as to output a Kth output signal. As k increases, the kth delayer may output a kth output signal representing an increasingly delayed clock signal CLK.

The switch unit 230 selects and outputs either the clock signal CLK or one of the first through nth output signals of the first through nth delayers 210_1 through 210_{—}n as a delayed clock signal CLKD, in response to a control signal CON<n:0>. The switch unit 230 may include a reference switch SW0, and first through nth switches SW1 through SWn. The reference switch SW0 controls connection between input and output terminals of the delay unit 150. In more detail, the reference switch SW0 may output the clock signal CLK as the delayed clock signal CLKD without a delay, in response to a control signal CON<0>. The first switch SW1 controls connection between an output terminal of the first delayer 210_1 and the output terminal of the delay unit 150. In more detail, the first switch SW1 may output the output signal of the first delayer 210_1 as the delayed clock signal CLKD, in response to a control signal CON<1>. A kth switch controls connection between an output terminal of a kth delayer and the output terminal of the delay unit 150, and may output an output signal of the kth delayer 210_{—}k as the delayed clock signal CLKD, in response to a control signal CON<k>. The reference switch SW0, and the first through nth switches SW1 through SWn may be fuses that may be fused in response to the control signal CON<n:0>. If the reference switch SW0, and the first through nth switches SW1 through SWn are fuses, the fuses other than a selected fuse may be cut or blown and therefore not output a signal from the output terminal of the corresponding delayer.

FIG. 3 is a schematic diagram of a ZQ calibration circuit 300 as an example of the calibration circuit 110 illustrated in FIG. 1.

Referring to FIG. 3, the ZQ calibration circuit 300 may include a first pull-up circuit 310, a first counter 320, a second pull-up circuit 330, a first comparator COMP_1, a second comparator COMP_2, a second counter 340, and a pull-down circuit 350.

A ZQ pad ZQ of the semiconductor device 100 illustrated in FIG. 1 is connected to an end of an external resistor R and an other end of the external resistor R is connected to a ground voltage VSS. The first pull-up circuit 310 is located between the ZQ pad ZQ and a source voltage (not shown). Thus, the ZQ pad ZQ is connected to the source voltage through the first pull-up circuit 310 and is connected to the ground voltage VSS through the external resistor R. A voltage level of a reference voltage VREF may be half of a voltage level of the source voltage. An impedance of the first pull-up circuit 310 may become identical to the impedance of the external resistor R by adjusting a voltage level of the ZQ pad ZQ to be identical to the voltage level of the reference voltage VREF. In more detail, the first comparator COMP_1 may adjust the impedance of the first pull-up circuit 310 by comparing the voltage level of the ZQ pad ZQ and the voltage level of the reference voltage VREF and outputting a signal to the first counter 320. Also, an impedance of the second pull-up circuit 330 may become identical to the impedance of the external resistor R by adjusting the impedance of the first pull-up circuit 310 to be identical to the impedance of the external resistor R. The second pull-up circuit 330 is connected between the source voltage and a replica pad REPLICA. The pull-down circuit 350 is connected between the replica pad REPLICA and the ground voltage VSS (not shown). An impedance of the pull-down circuit 350 may become identical to the impedance of the external resistor R by adjusting a voltage level of the replica pad REPLICA to be identical to the voltage level of the ZQ pad ZQ. In more detail, the second comparator COMP_2 may adjust the impedance of the pull-down circuit 350 by comparing the voltage level of the replica pad REPLICA and the voltage level of the ZQ pad ZQ and outputting a signal to the second counter 320.

Output signals of the first and second counters 320 and 340 are identical and output as output signal CAL<n:0> of the ZQ calibration circuit 300. In addition, the output signals of the first counter 320 are input to the first pull-up circuit 310 and the second pull-up circuit 330. The output signals of the second counter 320 are input to the pull-down circuit 350. In more detail, the output signal CAL<n:0> of the ZQ calibration circuit 300 controls gates of transistors of the output driver 170 illustrated in FIG. 1.

FIG. 4 is a graph showing a correlation between a signal transmission speed of the semiconductor device 100 illustrated in FIG. 1 and an output signal CAL<n:0> of the calibration circuit 110 illustrated in FIG. 1.

Referring to FIGS. 1 and 4, the graph of FIG. 4 shows the correlation between the signal transmission speed of the semiconductor device 100 and the output signal CAL<n:0> of the calibration circuit 110 when a source voltage VDD of the semiconductor device 100 varies between 1.1V to 1.35V. Although FIG. 4 shows that the source voltage VDD of the semiconductor device 100 varies between 1.1V to 1.35V, example embodiments of the invention are not limited thereto. The correlation shown in FIG. 4 may also be applied to the source voltage VDD of other voltage levels, if necessary.

Initially, a case when the source voltage VDD is fixed to 1.1V will now be described. A horizontal axis represents the signal transmission speed of the semiconductor device 100, and a vertical axis represents a value obtained by converting the output signal CAL<n:0> of the calibration circuit 110 into a decimal. The signal transmission speed includes a slow signal transmission speed SS, a typical signal transmission speed TT, and a fast signal transmission speed FF. In more detail, when a signal is transmitted, turn-on currents of NMOS and PMOS transistors may be small at the slow signal transmission speed SS, typical at the typical signal transmission speed TT, and large at the fast signal transmission speed FF. Also, if the source voltage VDD varies, for example, if the source voltage VDD varies from 1.1V to 1.15V, a line graph at 1.15V is different from a line graph at 1.1V. For example, as a voltage level of the source voltage VDD varies, the output signal CAL<n:0> of the calibration circuit 110 has different values. However, at each voltage level of the source voltage VDD, the output signal CAL<n:0> of the calibration circuit 110 linearly varies according to the signal transmission speed. Thus, the control unit 130 may determine the signal transmission speed of the semiconductor device 100 in response to the output signal CAL<n:0> of the calibration circuit 110, by using the graph of FIG. 4.

FIG. 5 is a graph showing variations in data access time tAC according to an embodiment of the invention, and variations in data access time tAC according to conventional art.

Referring to FIG. 5, (a) represents variations in data access time tAC in accordance with a signal transmission speed, according to conventional art, and (b) represents variations in data access time tAC in accordance with a signal transmission speed, according to an embodiment of the invention.

According to the conventional art, as represented by (a), the data access time tAC is long at a slow signal transmission speed SS and is short at a fast signal transmission speed FF. However, according to an embodiment of the invention, as represented by (b), the data access time tAC is constantly maintained to be the same regardless of variations in the signal transmission speed.

A method of constantly maintaining the data access time tAC, as represented by (b), will now be described with reference to FIGS. 1 through 5.

Referring to FIGS. 1 through 5, the control unit 130 determines a signal transmission speed of the semiconductor device 100 in response to an output signal CAL<n:0> of the calibration circuit 110. The control signal 130 outputs a control signal CON<n:0> in order to delay a clock signal CLK for a desired (or alternatively, predetermined) period of time in correspondence with the signal transmission speed. The delay unit 150 delays the clock signal CLK in response to the control signal CON<n:0> and outputs a delayed clock signal CLKD. The output driver 170 outputs data DATA in synchronization with the delayed clock signal CLKD.

For example, if a source voltage VDD is 1.1V, it may be assumed that the output signal CAL<n:0> of the calibration circuit 110 is converted into a decimal having a value 19. As shown in FIG. 4, the signal transmission speed in this case corresponds to a median of a typical signal transmission speed TT and, as shown in FIG. 5, the data access time tAC at the median of the typical signal transmission speed TT is 3.75 nanosecond (ns). Thus, the control unit 130 controls the delay unit 150 to delay the clock signal CLK for 0.65 ns.

For example, it may be assumed that a delay of 0.65 ns is made when the clock signal CLK is transmitted through the first through third delayers 210_1 through 210_3, and that control signals CON<0> through CON<n> respectively corresponding to the reference switch SW0 and the first through nth switches SW1 through SWn are turned on in a first logic state and are turned off in a second logic state. Hereinafter, the first logic state may be a logic high state and the second logic state is a logic low state. However, the same effect of may also be achieved when the first logic state is the logic low state and the second logic state is the logic high state.

The control unit 130 outputs the control signal CON<n:0>, in which the control signal CON<3> is in the first logic state and the other control signals CON<0> through CON<2> and CON<4> through CON<n> are in the second logic state, to the delay unit 150. The delay unit 150 outputs an output signal of the third delayer 210_3 as the delayed clock signal CLKD in response to the control signal CON<n:0>. Thus, since the output driver 170 outputs the data DATA in synchronization with the delayed clock signal CLKD, the data access time tAC is 4.40 ns.

For example, if the source voltage VDD is 1.1V, it may be assumed that the output signal CAL<n:0> of the calibration circuit 110 is converted into a decimal having a value 17. Thus, as shown in FIG. 4, the signal transmission speed in this case corresponds to a median of a fast signal transmission speed FF and, as shown in FIG. 5, the data access time tAC at the median of the fast signal transmission speed FF is 3.30 ns. Thus, the control unit 130 controls the delay unit 150 to delay the clock signal CLK for 1.10 ns.

For example, it may be assumed that a delay of 1.1 ns is made when the clock signal CLK is transmitted through the first through nth delayers 210_1 through 210_{—}n. Thus, the control unit 130 outputs the control signal CON<n:0>, in which the control signal CON<n> is in the first logic state and the other control signals CON<0> through CON<n−1> are in the second logic state, to the delay unit 150. The delay unit 150 outputs an output signal of the nth delayer 210_{—}n as the delayed clock signal CLKD in response to the control signal CON<n:0>. Thus, since the output driver 170 outputs the data DATA in synchronization with the delayed clock signal CLKD, the data access time tAC is 4.40 ns.

For example, if the source voltage VDD is 1.1V, it is assumed that the output signal CAL<n:0> of the calibration circuit 110 is converted into a decimal having a value 22. Thus, as shown in FIG. 4, the signal transmission speed in this case corresponds to a median of a slow signal transmission speed SS and, as shown in FIG. 5, the data access time tAC at the median of the slow signal transmission speed SS is 4.40 ns. Thus, the control unit 130 controls the delay unit 150 not to delay the clock signal CLK. In more detail, the control unit 130 outputs the control signal CON<n:0>, in which the control signal CON<0> is in the first logic state and the other control signals CON<1> through CON<n> are in the second logic state, to the delay unit 150. The delay unit 150 outputs the clock signal CLK as the delayed clock signal CLKD without a delay, in response to the control signal CON<n:0>. Thus, since the output driver 170 outputs the data DATA in synchronization with the delayed clock signal CLKD, the data access time tAC is 4.40 ns.

Accordingly, when the source voltage VDD of a desired (or alternatively, predetermined) voltage level is applied to the semiconductor device 100, the delay unit 150 delays the clock signal CLK for a desired (or alternatively, predetermined) period of time in response to the control signal CON<n:0> and thus the data access time tAC may be constantly maintained.

While the invention has been particularly shown and described with reference to example embodiments thereof, terms used herein to describe the invention are for descriptive purposes only and are not intended to limit the scope of the invention. Accordingly, it will be understood by one of ordinary skill in the art that various changes in form and details may be made therein without departing from the spirit and scope of the following claims.

What is claimed is:

1. A semiconductor device comprising:
a calibration circuit configured to output an output signal;
a control unit configured to generate and output a control signal in response to the output signal of the calibration circuit, where the control unit generates the control signal by using a correlation between a signal transmission speed of the semiconductor device and the output signal of the calibration circuit; and
a delay unit configured to delay a clock signal in response to the control signal and output the delayed clock signal to the output driver.

2. The semiconductor device of claim 1, wherein the calibration circuit includes a ZQ calibration circuit.

3. The semiconductor device of claim 1, wherein the delay unit delays the clock signal in response to the control signal so that a constant time period is maintained between the clock signal and data output from the semiconductor device in synchronization with the clock signal.

4. The semiconductor device of claim 1, wherein the delay unit includes,
a plurality of delays configured to delay the clock signal, and
a switch unit configured to select and output one of the clock signal and an output signal of one of the plurality of delays, in response to the control signal.

5. The semiconductor device of claim 4, wherein each of the plurality of delays includes an inverter chain having a plurality of inverters.

6. The semiconductor device of claim 4, wherein the switch unit includes a plurality of switches, with the plurality of switches further including:
a reference switch configured to control a connection between input and output terminals of the delay unit; and
a plurality of delay switches respectively configured to control a connection between output terminals of the corresponding plurality of delays and the output terminal of the delay unit.

7. The semiconductor device of claim 6, wherein the plurality of switches of the switch unit are fuses that are selectively one of cut and blown in response to the control signal.

8. The semiconductor device of claim 6, wherein the control unit outputs the control signal that turns on one of the plurality of switches of the switch unit and turns off a remaining of the plurality of switches of the switch unit.

9. The semiconductor device of claim 1, wherein the control signal includes a plurality of bits.

10. The semiconductor device of claim 1, wherein the control unit correlates the correlation between the signal transmission speed of the semiconductor device and the output signal of the calibration circuit if a source voltage of the semiconductor device is at a desired voltage level.

11. The semiconductor device of claim 1, wherein the output driver outputs data in synchronization with the delayed clock signal.

12. The semiconductor device of claim 12, wherein the output driver comprises:
a switch configured to output the data in response to the delayed clock signal;
a first inverter configured to receive and invert the data output from the switch;
a second inverter configured to receive and invert an output of the first inverter; and
a DQ pad configured to a receive an output of the second inverter.

13. The semiconductor device of claim 1, wherein the delay unit outputs the delayed clock signal to the output driver through a plurality of lines and inverters.

14. The semiconductor device of claim 1, wherein the delay unit outputs the delayed clock signal to the output driver through at least one of a plurality of n-type metal-oxide-semiconductors (NMOSs) and p-type metal-oxide-semiconductors (PMOSs), where the NMOSs and the PMOSs transmit the delayed clock signal at different speeds according to a size of a turn-on current for each of the at least one of the plurality of the NMOSs and the PMOSs.

15. A semiconductor device comprising:
a control unit configured to generate and output a control signal in response to an output signal of a calibration circuit, where the control unit generates the control signal by using a correlation between a signal transmission speed of the semiconductor device and the output signal of the calibration circuit; and
a delay unit configured to delay a clock signal in response to the control signal and to output the delayed clock signal to the output driver, where the delay unit delays the clock signal in response to the control signal such that a constant time period is maintained between the clock signal and data output from the semiconductor device in synchronization with the clock signal.

16. The semiconductor device of claim 15, wherein the delay unit includes,
a plurality of delays configured to delay the clock signal, and
a switch unit configured to select and output one of the clock signal and an output signal of one of the plurality of delays, in response to the control signal.

17. The semiconductor device of claim 16, wherein the switch unit includes a plurality of switches, with the plurality of switches further including:
a reference switch configured to control a connection between input and output terminals of the delay unit; and
a plurality of delay switches respectively configured to control a connection between output terminals of the corresponding plurality of delays and the output terminal of the delay unit.

18. The semiconductor device of claim 17, wherein the control unit outputs the control signal that turns on one of the plurality of switches of the switch unit and turns off a remaining of the plurality of switches of the switch unit.

19. A semiconductor device comprising:
a calibration circuit configured to output an output signal based on adjusting an internal impedance in response to a voltage level;
a control unit configured to generate and output a control signal in response to the output signal, where the control unit generates the control signal by using a correlation between a signal transmission speed of the semiconductor device and the output signal of the calibration circuit;
a delay unit configured to delay a clock signal in response to the control signal and output the delayed clock signal to an output driver; and
the output driver configured to output data in synchronization with the delayed clock signal.

20. The semiconductor device of claim 16, wherein the delay unit delays the clock signal in response to the control signal so that a constant time period is maintained between the clock signal and data output from the semiconductor device in synchronization with the clock signal.
